(19) United States
(12) Patent Application Publication
(10) Pub. No.: US 2017/0088947 A1
(43) Pub. Date: Mar. 30, 2017

(54) CHEMICAL VAPOR DEPOSITION FUNCTIONALIZATION

(71) Applicant: SILCOTEK CORP., Bellefonte, PA (US)

(72) Inventor: David A. SMITH, Bellefonte, PA (US)

(21) Appl. No.: 15/276,043

(22) Filed: Sep. 26, 2016

Related U.S. Application Data
(60) Provisional application No. 62/234,095, filed on Sep. 29, 2015.

(51) Int. Cl. C23C 16/44; C23C 16/22

(52) U.S. Cl. CPC C23C 16/44; C23C 16/22

(57) ABSTRACT

Thermal chemical vapor deposition functionalization processes, thermal chemical vapor deposition functionalizations, and thermal chemical vapor deposition functionalized articles are disclosed. The thermal chemical vapor deposition functionalization process includes modifying a surface by thermally reacting a gas to form a thermal chemical vapor deposition functionalization on the surface. The gas is selected from the group consisting of methyltrimethoxysilane, methyltriethoxysilane, dimethyldimethoxysilane, dimethyldiethoxysilane, trimethylmethoxysilane, trimethylethoxysilane, and combinations thereof. The thermal chemical vapor deposition functionalization and the thermal chemical vapor deposition functionalized article are produced by the thermal chemical vapor deposition process.

### FIELD OF THE INVENTION

The present invention is directed to thermal chemical vapor deposition. More particularly, the present invention is directed to thermal chemical vapor deposition functionalization processes, thermal chemical vapor deposition functionalizations, and thermal chemical vapor deposition functionalized articles.

### BACKGROUND OF THE INVENTION

Hydrophobicity and oleophobicity can be desirable properties. Such properties can have additional applications and permit use of additional materials in additional environments. However, concurrent hydrophobicity and oleophobicity are not easily achieved. Many have failed to produce hydrophobicity and oleophobicity in a cost effective manner and/or within environmentally-friendly or safe conditions.

Some hydrophobic and oleophobic materials are produced using fluorine-based materials. Fluorine-based materials can have desirable properties. However, fluorine-based materials can be expensive and/or can require additional considerations due to the disfavored environmental and health concerns associated with fluorine-containing materials.

Thermal chemical vapor deposition functionalization processes, thermal chemical vapor deposition functionalizations, and thermal chemical vapor deposition functionalized articles that show one or more improvements in comparison to the prior art would be desirable in the art.

### BRIEF DESCRIPTION OF THE INVENTION

In an embodiment, a thermal chemical vapor deposition functionalization process includes modifying a surface by thermally reacting a gas to form a thermal chemical vapor deposition functionalization on the surface. The gas is selected from the group consisting of methyltrimethoxysilane, methyltriethoxysilane, dimethyldimethoxysilane, dimethyldiethoxysilane, trimethylmethoxysilane, trimethylethoxysilane, and combinations thereof.

In another embodiment, a thermal chemical vapor deposition functionalization includes a thermal reaction of a gas, the gas being selected from the group consisting of methyltrimethoxysilane, methyltriethoxysilane, dimethyldimethoxysilane, dimethyldiethoxysilane, trimethylmethoxysilane, trimethylethoxysilane, and combinations thereof.

In another embodiment, a thermal chemical vapor deposition functionalized article includes a thermal chemical vapor deposition functionalization, the thermal chemical vapor deposition functionalization comprising a thermal reaction of a gas, the gas being selected from the group consisting of methyltrimethoxysilane, methyltriethoxysilane, dimethyldimethoxysilane, dimethyldiethoxysilane, trimethylmethoxysilane, trimethylethoxysilane, and combinations thereof.

Other features and advantages of the present invention will be apparent from the following more detailed description, which illustrates, by way of example, the principles of the invention.

### DETAILED DESCRIPTION OF THE INVENTION

Provided are thermal chemical vapor deposition functionalization processes, thermal chemical vapor deposition functionalizations, and thermal chemical vapor deposition functionalized articles. Embodiments of the present disclosure, for example, in comparison to concepts failing to include one or more of the features disclosed herein, permit production of a materials that is hydrophobic (having a contact and of greater than 90 degrees for water) and/or oleophobic (having a contact and of greater than 50 degrees for hexadecane), permit functionalizations to be produced that do not include or do not require use of fluorine-based materials, permit functionalization of a wider range of geometries (for example, narrow channels/tubes, three-dimensionally complex geometries, and/or hidden or non-line-of-site geometries, such as, in needles, tubes, probes, fixtures, complex planar and/or non-planar geometry articles, simple non-planar and/or planar geometry articles, and combinations thereof), permit functionalization of a bulk of articles, or permit a combination thereof. As used herein, the term “functionalization” and grammatical variations thereof refer to bonding of a terminal group to a surface.

According to the disclosure, the thermal chemical vapor deposition functionalization process includes modifying a surface by thermally reacting a gas in one or both of a chamber(s) and/or a vessel(s) to form a thermal chemical vapor deposition functionalization on the surface. The gas is selected from the group consisting of methyltrimethoxysilane, methyltriethoxysilane, dimethyldimethoxysilane, dimethyldiethoxysilane, trimethylmethoxysilane, trimethylethoxysilane, and combinations thereof. The thermal chemical vapor deposition functionalization process produced the thermal chemical vapor deposition functionalization and the thermal chemical vapor deposition functionalized article.

The surface is a layer on a substrate or is the substrate itself In one embodiment, the surface is or includes a stainless steel surface (martensitic or austenitic), a nickel-based alloy, a metal surface, a metallic surface (ferrous or non-ferrous; tempered or non-tempered; and/or equiaxed, directionally-solidified, or single crystal), a ceramic surface, a ceramic matrix composite surface, a glass surface, ceramic matrix composite surface, a composite metal surface, a coated surface, a fiber surface, a foil surface, a film, a polymeric surface (such as, polyether etherketone), and/or any other suitable surface capable of withstanding operational conditions of the thermal chemical vapor deposition process.

In another embodiment, the surface is formed from a silane-based material, for example, formed from dimethylsilane (for example, in gaseous form), trimethylsilane, dialkylsilyl dihydride, alkylsilyl trihydride, non-pyrophoric species (for example, dialkylsilyl dihydride and/or alkylsilyl trihydride), thermally reacted material (for example, carbosilane and/or carboxysilane, such as, amorphous carbosilane and/or amorphous carboxysilane), species capable of a recombination of carbosilyl (disilyl or trisilyl fragments), and/or any other suitable silane-based material. Such materials may be applied iteratively and/or with purges in between, for example, with an inert gas (such as, nitrogen, helium, and/or argon, as a partial pressure dilutant).

Additionally, in further embodiments, the surface is treated. Suitable treatments include, but are not limited to, exposure to water (alone, with zero air, or with an inert gas), oxygen (for example, at a concentration, by weight, of at least 50%), air (for example, alone, not alone, and/or as zero air), nitrous oxide, ozone, peroxide, or a combination thereof. As used herein, the term “zero air” refers to atmospheric air having less than 0.1 ppm total hydrocarbons. The term “air” generally refers to a gaseous fluid, by weight, of mostly nitrogen, with the oxygen being the second highest concentration species within. For example, in one embodiment, the nitrogen is present at a concentration, by weight, of at least 70% (for example, between 75% and 76%) and oxygen is present at a concentration, by weight, of at least 20% (for example, between 23% and 24%).

The thermal chemical vapor deposition functionalization process is within a temperature range to thermally react the gas and deposition on the surface. Suitable temperatures include, but are not limited to, between 100° C. and 700° C., between 100° C. and 450° C., between 100° C. and 300° C., between 200° C. and 500° C., between 300° C. and 600° C., between 450° C. and 700° C., 700° C., 450° C., 100° C., between 200° C. and 600° C., between 300° C. and 600° C., between 400° C. and 500° C., 300° C., 400° C., 500° C., 600° C., or any suitable combination, sub-combination, range, or sub-range thereof.

The thermal chemical vapor deposition functionalization process is within a pressure range facilitating the thermal reaction of the gas and the deposition on the surface. Suitable pressures include, but are not limited to, between 0.01 psia and 200 psia, between 1.0 psia and 100 psia, between 5 psia and 40 psia, between 20 psia and 25 psia, 1.0 psia, 5 psia, 20 psia, 23 psia, 25 psia, 40 psia, 100 psia, 200 psia, or any suitable combination, sub-combination, range, or sub-range therein.

Suitable dimensions for the chamber and/or vessel used in the thermal chemical vapor deposition process include, but are not limited to, having a minimum width of greater than 5 cm, of greater than 10 cm, greater than 20 cm, greater than 30 cm, greater than 100 cm, greater than 300 cm, greater than 1,000 cm, between 10 cm and 100 cm, between 100 cm and 300 cm, between 100 cm and 1,000 cm, between 300 cm and 1,000 cm, any other minimum width capable of uniform or substantially uniform heating, or any suitable combination, sub-combination, range, or sub-range therein. Suitable volumes include, but are not limited to, at least 1,000 cm³, greater than 3,000 cm³, greater than 5,000 cm³, greater than 10,000 cm³, greater than 20,000 cm³, between 3,000 cm³ and 5,000 cm³, between 5,000 cm³ and 10,000 cm³, between 5,000 cm³ and 20,000 cm³, between 10,000 cm³ and 20,000 cm³, any other volumes capable of uniform or substantially uniform heating, or any suitable combination, sub-combination, range, or sub-range therein.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A thermal chemical vapor deposition functionalization process, comprising:
modifying a surface by thermally reacting a gas to form a thermal chemical vapor deposition functionalization on the surface;
wherein the gas is selected from the group consisting of methyltrimethoxysilane, methyltriethoxysilane, dimethyldimethoxysilane, dim ethyldiethoxysilane, trimethylmethoxysilane, trimethylethoxysilane, and combinations thereof.

2. The thermal chemical vapor deposition functionalization process of claim 1, wherein the thermal chemical vapor deposition functionalization is hydrophobic and oleophobic.

3. The thermal chemical vapor deposition functionalization process of claim 1, wherein the thermally reacting of the gas is within a temperature range of between 100° C. and 700° C.

4. The thermal chemical vapor deposition functionalization process of claim 1, wherein the thermally reacting of the gas is within a temperature range of between 100° C. and 450° C.

5. The thermal chemical vapor deposition functionalization process of claim 1, wherein the thermally reacting of the gas is within a temperature range of between 300° C. and 600° C.

6. The thermal chemical vapor deposition functionalization process of claim 1, wherein the thermally reacting of the gas is within a temperature range of between 250° C. and 400° C.

7. The thermal chemical vapor deposition functionalization process of claim 1, wherein the thermally reacting of the gas is within a pressure range of between 0.01 psia and 200 psia.

8. The thermal chemical vapor deposition functionalization process of claim 1, wherein the thermally reacting of the gas is within a pressure range of between 1.0 psia and 100 psia.

9. The thermal chemical vapor deposition functionalization process of claim 1, wherein the thermally reacting of the gas is within a pressure range of between 5 psia and 40 psia.

10. The thermal chemical vapor deposition functionalization process of claim 1, wherein the thermally reacting of the gas is within a chamber or vessel having a volumetric range of between 3,000 cm³ and 5,000 cm³.

11. The thermal chemical vapor deposition functionalization process of claim 1, wherein the thermally reacting of the gas is within a chamber or vessel having a volumetric range of between 10,000 cm³ and 20,000 cm³.

12. The thermal chemical vapor deposition functionalization process of claim 1, wherein the surface is a layer on a substrate.

13. The thermal chemical vapor deposition functionalization process of claim 1, wherein the surface is a layer on a substrate, the layer being formed from a silane-based material.

14. The thermal chemical vapor deposition functionalization process of claim 1, wherein the surface is a substrate.

15. The thermal chemical vapor deposition functionalization process of claim 1, wherein the surface is or includes a metal.

16. The thermal chemical vapor deposition functionalization process of claim 1, wherein the surface is or includes stainless steel.

17. The thermal chemical vapor deposition functionalization process of claim 1, wherein the surface is or includes aluminum.

18. The thermal chemical vapor deposition functionalization process of claim 1, wherein the surface is or includes glass.

19. A thermal chemical vapor deposition functionalization, comprising a thermal reaction of a gas, the gas being selected from the group consisting of methyltrimethoxysilane, methyltriethoxysilane, dimethyldimethoxysilane, dimethyldiethoxysilane, trimethylmethoxysilane, trimethylethoxysilane, and combinations thereof.

20. A thermal chemical vapor deposition functionalized article, comprising a thermal chemical vapor deposition functionalization, the thermal chemical vapor deposition functionalization comprising a thermal reaction of a gas, the gas being selected from the group consisting of methyltrimethoxysilane, methyltriethoxysilane, dim ethyl dimethoxysilane, dimethyldiethoxysilane, trimethylmethoxysilane, trimethylethoxysilane, and combinations thereof.
